(19) United States
(12) Patent Application Publication
(10) Pub. No.: US 2005/0040527 A1
(43) Pub. Date: Feb. 24, 2005

(54) [CHIP STRUCTURE]

(76) Inventor: Min-Lung Huang, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,908

(22) Filed: Aug. 12, 2004

(30) Foreign Application Priority Data
Aug. 21, 2003 (TW) 92122953

(51) Int. Cl. H01L 21/44

(52) U.S. Cl. 257/736

(57) ABSTRACT

A chip structure comprising a chip, a spacing pad, a passivation layer, an under-bump metallic (UBM) layer and a conductive bump is provided. A plurality of bonding pads is disposed on the active surface of the chip. The spacing pad is disposed between the bonding pad and the UBM layer for reducing the possibility of broken circuit caused by the electro-migration between the bonding pad and the UBM layer. The base of the conductive bump is connected to the UBM layer so that the conductive bump can serve as a conductive structure for connecting with an external circuit.

### CROSS REFERENCE TO RELATED APPLICATIONS

This application claims the priority benefit of Taiwan application serial no. 92122953, filed Aug. 21, 2003.

### BACKGROUND OF INVENTION

1. Field of the Invention

The present invention relates to a chip structure. More particularly, the present invention relates to a conductive structure on the bonding pad of a chip adapted to flip chip bonding.

2. Description of Related Art

The fabrication of semiconductor products can be roughly divided into three stages, namely, the production of raw wafers, the fabrication of integrated circuit (IC) chips and the packaging of the IC chips. An IC chip is the end product of a series of steps including wafer production, circuit design, circuit fabrication and wafer cutting. After the wafer is diced up to form independent IC chips, the bonding pads on each IC chip are electrically connected to an external contact and then encapsulated to form a chip package. The body of the chip package provides an effective barrier against the infiltration of moisture, the transfer of heat or the coupling with external signals. Furthermore, the package also serves as a medium for electrically connecting with an external circuit such as a printed circuit board (PCB) or other packaging substrate.

To connect the aforementioned chip with a packaging substrate, wires and/or conductive bumps are frequently used. In the flip-chip interconnect technology, a chip having an array of conductive bumps formed on the bonding pads is flipped over, aligned with a corresponding array of contacts on a packaging substrate and then the bumps and the contacts are bonded together. Therefore, the chip is able to communicate with an external device through the bumps, the surface contacts and the internal circuits of the packaging substrate.

FIG. 1 is a schematic cross-sectional view of a conventional chip structure. As shown in FIG. 1, each chip 100 has a plurality of bonding pads 110 (only one is shown) serving as signal transmission contacts. The bonding pads 110 are frequently disposed on an active surface 102 of the chip 100 in an array format so that the total number of contacts on the chip 100 is maximized. To avoid contamination by impurities or mechanical damage, a passivation layer 104 is formed over the active surface 102 of the chip 100. The passivation layer 104 is fabricated by depositing an organic passivation material or an inorganic passivation material over the active surface 102 of the chip 100 such that the top surface 112 of the bonding pads 110 is exposed through an opening 106. The opening 106 serves as a contact window for attaching a bump in a subsequent process.

As shown in FIG. 1, a bump process is performed to produce an under-bump metallic (UBM) layer 120 and a conductive bump 130 over each bonding pad 110. The UBM layer 120 and the conductive bump 130 together serve as an electrical structure for forming an electrical and mechanical connection with a packaging substrate (not shown). The UBM layer is disposed between the bonding pad 110 and the conductive bump 130 to increase the bondability between the bonding pad 110 and the conductive bump 130. In general, the UBM layer 120 is a composite layer comprising an adhesive layer 122, a barrier layer 124 and a wetting layer 126. The conductive bumps 130 are fabricated using Sn/Pb alloy, for example. Typically, the spherical configuration of the bumps is formed after a reflow process.

It should be noted that the UBM layer 120 forms a step coverage over the top surface 112 of the bonding pad 110 and around the periphery of the opening 106. Consequently, as the operating speed of the wafer is increased, a large current will flow through the bonding pad 110 leading to an angular change of greater than or equal to 90° in the current flow angle 108 towards the UBM layer 120. The sharp bending angle 108 of current flow often leads to a significant crowding in the current density and a corresponding crystal boundary expansion effect near the corner region, that is, severe electro-migration may occur. Hence, operating at a high current for long periods can easily lead to the lost of some metallic atoms within the UBM layer 120 and result in a broken circuit between the bonding pad 110 and the UBM layer 120. Ultimately, the life span of the chip 100 is shortened.

### SUMMARY OF INVENTION

Accordingly, the present invention is directed to a chip structure having a spacing pad disposed between a bonding pad and an under-bump metallic (UBM) layer for reducing the chance of having a broken circuit between the bonding pad and the UBM layer due to electro-migration. Hence, the working life of the chip is extended.

According to an embodiment of the present invention, a chip structure is provided. The chip structure mainly comprises a chip, a spacing pad, a first passivation layer, a second passivation layer, an under-bump metallic (UBM) layer and a conductive bump. The chip has at least a bonding pad disposed on an active surface. The first passivation layer covers the active surface but exposes the bonding pad through a first opening. Furthermore, the spacing pad is disposed on the bonding pad within the first opening of the first passivation layer. The second passivation layer covers the first passivation layer and the spacing pad is exposed through a second opening in the second passivation layer. The UBM layer covers the top surface of the spacing pad and the peripheral surface of the second opening. In addition, the base of the conductive bump is connected to the UBM layer such that the conductive bump serves as a conductive structure for connecting the chip with an external circuit.

The present invention is also directed to a conductive structure over a bonding pad on a chip. The chip has an active surface. At least a bonding pad is disposed on the active surface of the chip. The conductive structure on the bonding pad mainly comprises a spacing pad, a metallic bump pad and a conductive bump. The spacing pad is disposed between the bonding pad and the metallic bump pad for reducing the chance of having a broken circuit due to the electro-migration between the bonding pad and the metallic bump pad. In addition, the base of the conductive bump is connected to the metallic bump pad such that the conductive bump serves as a conductive structure for connecting the chip with an external circuit.

According to the aforementioned embodiment of the present invention, the conductive structure is vertically aligned above the bonding pad. When a current passing into the bonding pad change flow direction into the spacing pad and the UBM layer, the current density is attenuated through the spacing pad. Hence, the metallic atoms within the UBM layer are less readily lost through electromigration. In other words, the chance of having a broken circuit between the bonding pad and the UBM layer is reduced and the average working life of the chip in increased.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional chip structure.

FIG. 2 is a schematic cross-sectional view of a chip structure according to an embodiment of the present invention.

FIG. 3 is a schematic cross-sectional view of a chip structure according to another embodiment of the present invention.

FIG. 4 is a schematic cross-sectional view of a chip structure according to yet another embodiment of the present invention.

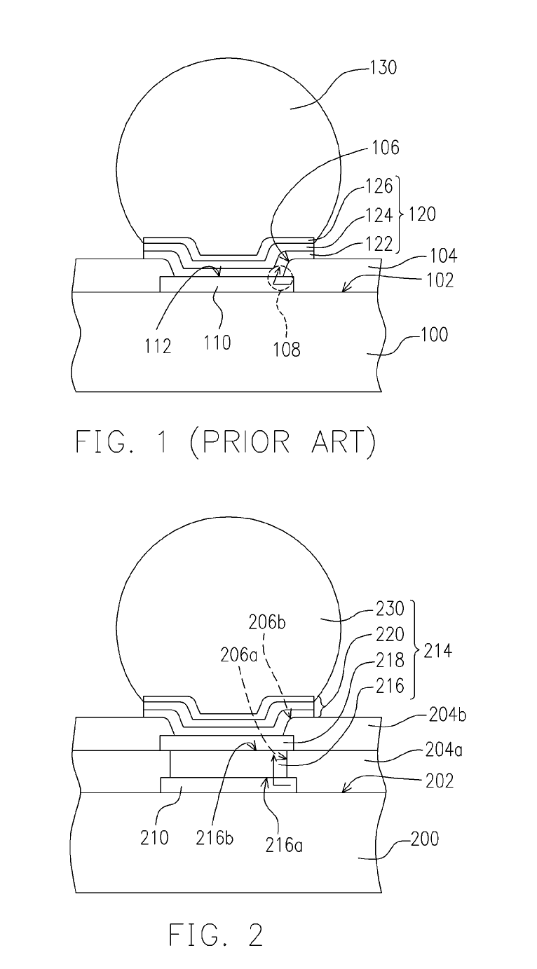

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

FIG. 2 is a schematic cross-sectional view of a chip structure according to a preferred embodiment of the present invention. As shown in FIG. 2, a plurality of bonding pads 210 (only one is shown) is disposed on the active surface of the chip 200. The bonding pads 210 form an array on the chip 200 and serve as contacts for communicating signals with external circuits. Furthermore, a conductive structure 214 is formed on the bonding pad 210 of the chip 200 to serve as medium for electrically connecting and structurally binding the chip 200 and a packaging substrate together. In the present embodiment, the conductive structure 214 comprises a spacing pad, a metallic bump pad 218, an under-bump metallic (UBM) layer 220 and a conductive bump 230. The spacing pad 216 and the metallic bump pad 218 are disposed between the bonding pad 210 and the UBM layer 220 to increase the separation between the bonding pad 210 and the UBM layer 220. Hence, the current density of a current passing from the surface 216a of the spacing pad 216 close to the bonding pad 210 to the surface 216b away from the bonding pad 210 is gradually attenuated. With a gradual reduction of current density, the metallic atoms within the UBM layer 220 are prevented from being lost through electro-migration and the probability of having a broken circuit between the bonding pad 110 and the UBM layer 120 is greatly reduced.

As shown in FIG. 2, the conductive structure 214 is vertically erected over the bonding pad 210. Furthermore, a first passivation layer 204a and a second passivation layer 204b are sequentially formed over the active surface 202 of the chip 200. The first passivation layer 204a and the second passivation layer 204b have a first opening 206a and a second opening 206b for disposing the conductive structure 214. The first passivation layer 204a and the second passivation layer 204b are formed, for example, by depositing organic passivation material or inorganic passivation material sequentially over the active surface 202 of the chip 200. In addition, the spacing pad 216 can be disposed on the bonding pad 210 within the first opening 206a of the first passivation layer 204a. The top surface 216b of the spacing pad 216 is roughly at the same height level as the top surface of the first passivation layer 206a. The metallic bump pad 218 is disposed between the spacing pad 216 and the UBM layer 220 and located at an intermediate position between the first opening 206a and the second opening 206b. The metallic bump pad 218 is, for example, fabricated using a metallic material having a high bondability with the spacing pad 216 and the UBM layer 220.

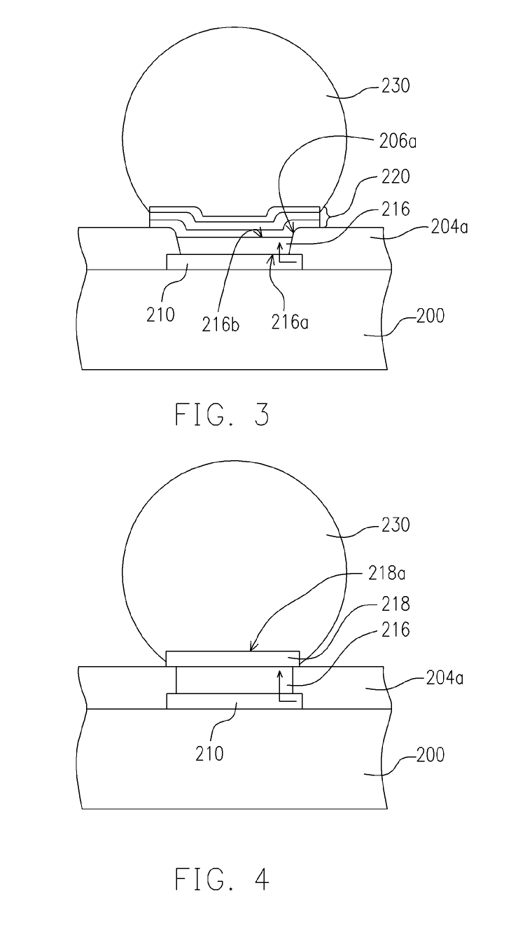

Obviously, if the bonding strength between the spacing pad 216 and the UBM layer 220 is strong, there is no need to form the metallic bump pad 218 in the first place. FIG. 3 is a schematic cross-sectional view of a chip structure according to another embodiment of the present invention. As shown in FIG. 3, the spacing pad 216 is accommodated within the opening 206a in the first passivation layer 204a. Furthermore, the top surface 216b of the spacing pad 216 rise to a level slightly below the top surface of the first passivation layer 204a to form a shallow depth opening 206a. In addition, the UBM layer 220 forms a step over the spacing pad 216 and the peripheral area of the opening 206a. The base of the conductive bump 230 and the UBM layer 220 are connected together to form a conductive structure for electrically and structurally connecting the chip 200 with an external device.

FIG. 4 is a schematic cross-sectional view of a chip structure according to yet another embodiment of the present invention. As shown in FIG. 4, the metallic bump pad 218 can be directly used as the UBM layer 220 when the bonding strength between the metallic bump pad 218 and the conductive bump 230 is strong. Here, the metallic bump pad 218 has a planar surface 218a and covers the top surface of the first passivation layer 204a. Thus, compared with a step covered UBM layer 220, the bonding strength of the metallic bump pad 218 with the conductive bump 230 is much better than the bonding strength of the UBM layer 220 with the conductive bump 230. In addition, the metallic bump pad 218 and the spacing pad 216 can be fabricated together using a low cost patterning process (for example, photolithographic and etching process) or an electroplating process. Since the aforementioned production process requires fewer and simpler steps to produce than the under-bump metallic layer, the production cost of the chip 200 can be significantly reduced.

In summary, the chip structure of the present invention has a spacing pad disposed on the active surface of the chip. One of the spacing pad surface is in contact with a bonding pad while the other surface is in contact with an under-bump metallic layer (or a metallic bump pad) to increase the separation between the bonding pad and the under-bump metallic layer (or the metallic bump pad). Consequently, the current density of the current passing from one of the spacing pad surface to the other is attenuated so that the rate of loss of metallic atoms from the under-ball metallic layer due to electro-migration is reduced. Ultimately, the probability of forming a broken circuit between the bonding pad and the under-ball metallic layer is minimized.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A chip structure, comprising:
a chip, having an active surface and at least a bonding pad disposed on the active surface;
a first passivation layer, disposed on the active surface, comprising at least a first opening exposing the bonding pad; and
a spacing pad, disposed on the bonding pad within the first opening.

2. The chip structure of claim 1, wherein the structure further comprises a metallic bump pad connected to the spacing pad and covering the peripheral surface around the first opening.

3. The chip structure of claim 2, further comprising a second passivation layer disposed over the first passivation layer such that the second passivation layer comprises at least a second opening that exposes the metallic bump pad.

4. The chip structure of claim 3, further comprising an under-bump metallic layer disposed on the top surface of the metallic bump pad and over the peripheral area around the second opening.

5. The chip structure of claim 4, wherein further comprising a conductive bump connected to the underbump metallic layer.

6. The chip structure of claim 3, further comprising a conductive bump connected to the metallic bump pad.

7. The chip structure of claim 1, further comprising an under-bump metallic layer covering a top surface of the spacing pad and the peripheral area around the first opening.

8. The chip structure of claim 7, further comprising a conductive bump connected to the under-bump metallic layer.

9. A conductive structure on the bonding pad of a chip having an active surface and at least a bonding pad disposed on the active surface, the conductive structure comprising:
a spacing pad, disposed on the bonding pad, comprising
a first surface and a corresponding second surface such that the first surface is in contact with the bonding pad;
a metallic bump pad, having a base in contact with the second surface of the spacing pad and a planar top surface; and
a conductive bump, having a base in contact with the planar top surface of the metallic bump pad.
